(19) United States
(12) Patent Application Publication
(10) Pub. No.: US 2006/0249789 A1
(43) Pub. Date: Nov. 9, 2006

(54) Inter-digitated silicon photodiode based optical receiver on SOI

(76) Inventor: Shrenik Deliwala, Andover, MA (US)

Correspondence Address: Gauthier & Connors LLP, Suite 2300, 225 Franklin Street, Boston, MA, 02110, US

(21) Appl. No.: 11/403,801

(22) Filed: Apr. 13, 2006

Related U.S. Application Data
(60) Provisional application No. 60/670,894, filed on Apr. 13, 2005.

(51) Int. Cl. H01L 27/12

(52) U.S. Cl. 257/347

(57) ABSTRACT

A photodiode includes SOI substrate and a plurality of interdigitated electrodes comprising of different doped regions. A silicon device region is defined in the SOI substrate having a thickness between 0.5 and 5 microns.

### PRIORITY INFORMATION

This application claims priority from provisional application Ser. No. 60/670,894 filed Apr. 13, 2005, which is incorporated herein by reference in its entirety.

### BACKGROUND OF THE INVENTION

The invention relates to the field of photodetectors, and in particular to a photodetector compatible with high speed integrated signal conditioning electronics to allow for many high-speed data oriented applications.

Silicon is a suitable semiconductor material for making optical photodetectors with wavelength range from ultraviolet to near infrared up to the band edge of silicon. Many detector structures and methods exist to make silicon detectors.

Integrated silicon detectors are less common or almost absent in high speed communication systems such as gigabit Ethernet or storage area networks since these operate at wavelengths that are either weakly absorbed in silicon—850 nm with absorption depth of almost 22 μm—or where silicon is transparent—1310 nm. At wavelengths near 850 nm, long absorption depth in normal incidence silicon detectors generates electron-hole pairs in region with low electric fields. This produces slow diffusing carriers. These carriers effectively limit the speed of operation of photodiodes Much effort has been expended to eliminating these diffusive carriers. These include deep trenched electrodes to collect carriers generated within the absorption depth, or vertical double diode type structures so that surface photodiodes maintain high-speed response while carriers generated deep within the silicon are collected by another diode and diverted electrically to prevent them from diffusing to fast near surface diodes.

Interdigitated detectors have also been made in the past to maintain high speed as metal-semiconductor-metal (MSM) or as lateral diodes in direct bandgap semiconductors with shallow absorption depth.

### SUMMARY OF THE INVENTION

According to one aspect of the invention, there is provided a photodiode. The photodiode includes SOI substrate and a plurality of interdigitated electrodes comprising of different doped regions. A silicon device region is defined in the SOI substrate having a thickness between 0.5 and 5 microns.

According to another aspect of the invention, there is provided a method of forming a photodiode. The method includes providing a SOI substrate and forming a plurality of interdigitated electrodes comprising of different doped regions. Also, the method includes forming a silicon device region a silicon device region is defined in the SOI substrate having a thickness between 0.5 and 5 microns.

According to another aspect of the invention, there is provided a photodetector. The photodetector a SOI substrate. A plurality of photodiodes is formed on the SOI substrate. Each of the photodiode includes a plurality of interdigitated electrodes comprising of different doped regions. A silicon device region is defined in the SOI substrate having a thickness between 0.5 and 5 microns.

### BRIEF DESCRIPTION OF THE DRAWINGS

FIGS. 1A-1B are schematic diagrams showing an illustrative embodiment of the inventive photodetector;

FIG. 2 is a schematic diagram shown another embodiment of the invention;

FIG. 3 is table approximating the depletion width for various bias voltages and base doping; and

FIG. 4 is a graph illustrating the sensitivity measurements of Si photodetector made in accordance with the invention.

### DETAILED DESCRIPTION OF THE INVENTION

The invention involves an integrated silicon detector or integrated photo-receiver for high-speed data-oriented applications. The integration of silicon detectors with appropriate signal conditioning electronics is important in many high-volume applications. An inventive photo-detector geometry is provided that is compatible with high speed integrated signal conditioning electronics to allow us to use these detectors for many high-speed data oriented applications. In the present invention, photodiode is added to the high-speed Silicon-Germanium bipolar process on SOI to integrate high quality signal conditioning electronics with photodetector. This inventive integrated photodetector has many advantages over the known photodetectors. The signal conditioning electronics can include bipolar or CMOS transistors or any combination thereof. By integrating the photodetector and on-chip signal conditioning electronics, the performance of an optical receiver can be optimized.

Most of the present solutions in the data communications at high speeds utilize discrete detector and a trans-impedance amplifiers (TIA) connected by bond wires and packaged in a housing. At high frequency, the quality of the bond wires and package conditions become increasingly important and needs to be accounted for in the design of the TIA/detector. It is often not appreciated that this two-piece solution reduces the detector area. This is because the total capacitance of the detector and the bond wire/bond pads determine both the available bandwidth and receiver sensitivity. By integrating a detector with TIA, one can eliminate bond pad capacitance which may be used to either increase the sensitivity, by keeping the photo-diode area same as before, or increasing the photo-diode area, which increases the capacitance, and easing the optical alignment. The ease of optical alignment can have direct impact on the overall cost since optical packaging contributes significantly to the overall cost of optical receiver.

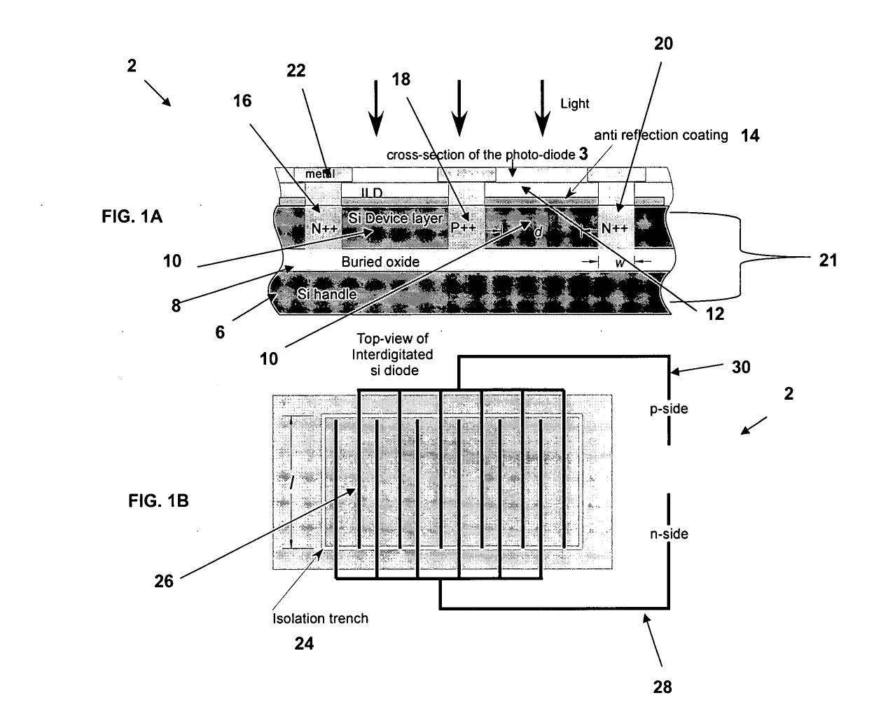

FIGS. 1A-1B show an illustrative embodiment of the inventive photodetector 2. FIG. 1A shows a cross-section of the photodetector 2 that is formed on a silicon-on-insulator (SOI) platform 21. The SOI platform 21 includes a Si handle 6, a buried oxide layer 8, and Si device layer 10 and is integrated with high speed bipolar electronics based on SiGe transistors such that all low level signal conditioning of the photo-current is performed on the integrated chip. The Si device layer 10 is placed between an interdigitated lateral p++ electrode 18 and interdigitated lateral n++ electrodes 16 and 20.

The doping of these regions are performed using standard doping techniques. Moreover, the thickness h of the Si device layer 10 is sized between 0.5 to 5 microns. For example, at 850 nm, 2.5 μm thick silicon device layer absorbs approximately 10-20% of the incident light. The actual absorption also depends on the thickness of the buried oxide since that provides partially reflective optical surface and the refractive index of the various interlayer dielectrics on top of the photodiode. For example, addition of optional thin anti-reflection layer 14 of silicon nitride can improve absorption by reducing reflection at the glass-silicon boundary. Note that absorption length in silicon in the relevant communication wavelength range of 750-870 nm is between 6-20 microns.

Thus, relatively thin silicon device layer with thickness in the range of 0.5-5 μm will not absorb all the incident light. On the other hand, the light transmitted thru the silicon device layer is absorbed in the silicon handle which is electrically isolated. Thus, all the photo-generated carriers in the device layer are in the region of strong electric field produced by biasing interdigitated electrodes. These carriers move rapidly to the electrodes owing to the electric field and thus the photodiode can maintain high-speed operation—critical to its operation in communication application. The thickness d represents the distance between the adjacent electrodes 16 and 18 or 18 and 20 used to form a photodiode 3. The arrangement of the interdigitated lateral p++ electrode 18 and interdigitated lateral n++ electrodes 20 with the Si device layer 10 produces a photodiode 3, the photodetector 2 includes an arrangement having many photodiodes 3 as shown in FIG. 1B.

Also, the photodiode 3 includes the metal lines 22 that are formed on the top regions of the interdigitated electrodes 16, 18, and 20 respectively. Several layers of inter-layer dielectrics 12 are used. Note one of those layers can include an anti-reflection (AR) coating layer 14 to enhance trapping of light to increase absorption. The anti-reflection (AR) coating layer 14 can be adjusted to optimize absorption. Standard and well characterized materials, such as silicon nitride, can easily act as anti-reflection coating layer. In some case, the AR coating layer 14 can be eliminated and the Fabry-Perot type resonances of the Si device layer 10 can be used to increase absorption in a narrow wavelength region. For thin metal lines 22 of width w, the ratio w/d determines the incident optical power blocked by the interdigitated metal lines 22 and thus reduction in the available optical power for photo-current production.

By building these devices on a SOI wafer 13, the photocurrent from diffusing electron-hole pairs are eliminated or reduced since it is possible to deplete most of the Si device layer 10. This does sacrifice optical responsivity at wavelengths where absorption depth is longer than the Si device layer 10 thickness d. Some of the loss of this responsivity can be compensated by a lower noise integrated TIA design by reducing the overall capacitance of the photodiode 3.

SOI based lateral photodiodes will also have a low capacitance. Each diode 3 formed by the interdigitated electrodes 16, 18, and 20 will have a capacitance from the metal lines 22 and from the reverse-biased diode. For thin metal lines 22 in glass-like dielectric, the overall capacitance will be dominated by the reverse biased diode. Each diode 3 has a capacitance c=εh l/d, where h is the height of the silicon device layer, l is the overall size of the diode as shown FIG. 1B, and c is the dielectric constant of silicon. Thus, the overall capacitance is given by N c where N is the number of diodes in the interdigitated structure. Note that the all of the resistances from each of the diodes appear in parallel and thus the structure has a resistance decreased by factor N. Thus, one may roughly estimate the intrinsic RC time constant of the interdigitated diode as given by a single diode of the structure.

FIG. 1B shows the top view of the interdigitated photodiodes 26 use to from the photodetector 2 of FIG. 1A. Note all of the photodiodes 26 formed between the interdigitated electrodes 28, 30 appear as parallel connected photodiodes having a n-side and p-side. Moreover, FIG. 1B shows the interdigitated electrodes 28, 30 having a length l. An isolation trench 24 can be made along the periphery of the diode region to electrically isolate the diodes. The scattered optical radiation beyond the trench 24 will not affect the high speed operation. Thus, the total capacitance is sum of the capacitance of the individual diodes but the effective resistance is N⁻¹ of the resistance of the individual diode.

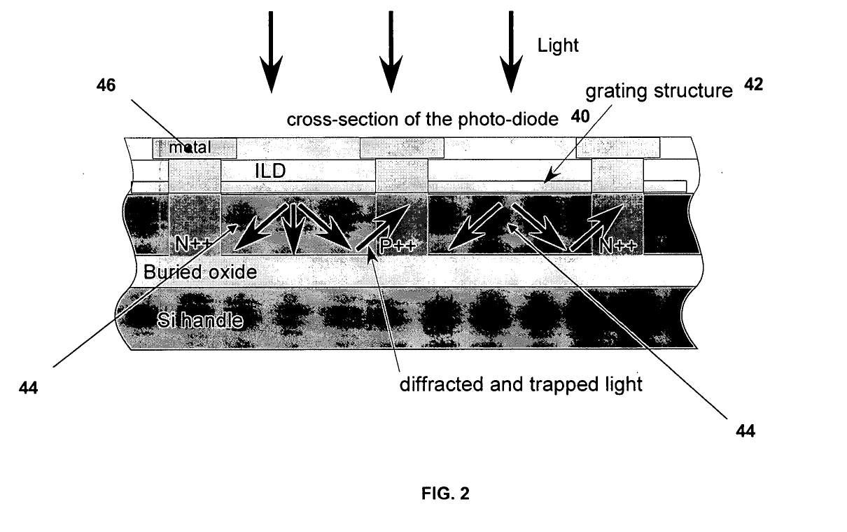

FIG. 2 shows another embodiment of the invention which is similar to the embodiment shown in FIG. 1A, except FIG. 2A uses a simple grating 42 like structure to diffract some portion of the normally incident light at angles greater than the total internal reflection angle of the metal lines 46 made from silicon glass. These diffracted rays will be trapped in the Si device layer 44 effectively increasing the responsivity. Furthermore, diffracted rays from near the edge of the diode 40 will generate electron-hole pairs far from the diode 40. These may be collected by a separate set of electrodes so that these do not cause slow response.

The distance between the electrodes is basically controlled by the required bandwidth, operating bias voltage, and the base doping of silicon device layer. The idea is to deplete the region between the electrodes so that electron-hole pairs drift at the saturation velocity υₛₐₜ in silicon of ≈10⁷ cm s⁻¹. Thus for a rise time of τ the depletion region between the electrodes d=υₛₐₜ τ. But the bias required to fully deplete the distance d depends on the base doping in the silicon device layer and the bias voltage. This is well known and can be easily computed for the actual doping profiles.

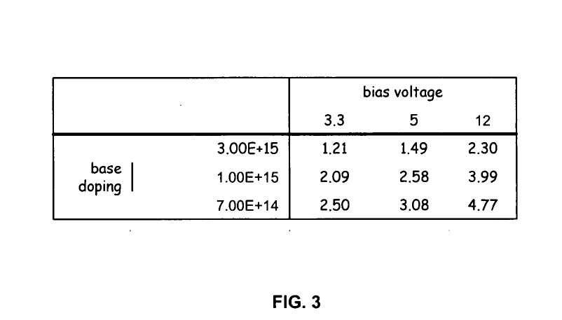

As a guide, FIG. 3 shows an approximate depletion width in microns for various bias voltages and base doping using depletion approximation. Typically, the base doping and the operating voltage will determine the electrode spacing rather than the transit time except at the very high frequencies. Note that greater the depletion at the operating reverse bias voltage, lower the capacitance. Thus, choice of higher resistivity silicon device layer can lead to lower capacitance and lower operating bias voltage. Lower capacitance leads to lower TIA noise and thus improved sensitivity for the integrated receiver.

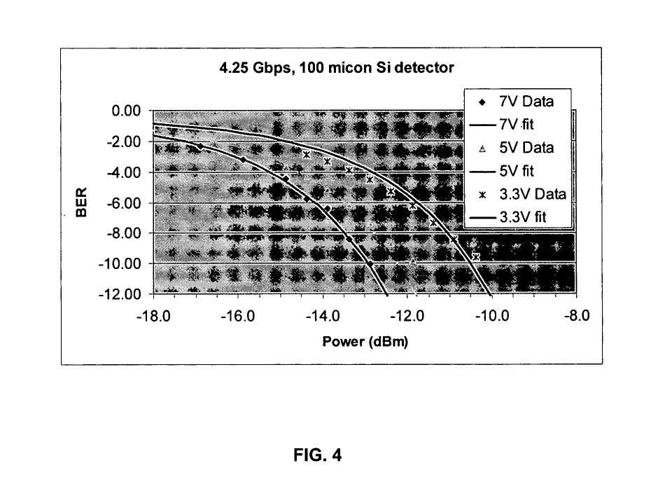

FIG. 4 shows a graph illustrating the sensitivity measurements of Si photodetector made in accordance with the invention. The sensitivity was measured at 830 nm. As shown in FIG. 4, the sensitivity is measured to be in the range of −10.3 to −13 dBm. This measurement was carried out with “unoptimized TIA design” and by detailed modeling one can expect substantial improvement in the sensitivity by optimizing the capacitance of the diode, and TIA circuit design.

Fewer interdigitated electrodes for a given size photodiode are needed as the distance is increased between the electrodes (by increasing the depletion region). This reduces the area blocked by the metal lines (thus increasing the light available for absorption) and decreases capacitance (which reduces noise in TIA).

Since bond pads or the like have been eliminated, one can make overall size of a diode such that the overall capacitance of the diode is consistent with the overall sensitivity requirements. This technology will allow for almost a 100 μm square detector operating at 5 gbps, receiver with −16 dBm sensitivity at bit error rate of 1E-12 at 850 nm. Most of the loss in sensitivity is due to blocked optical collection and poor absorption in a thin silicon device layer. Yet the above sensitivity is adequate for short-reach, high speed data communication. The inventive diode also allows enhanced blue absorption due to lack of highly doped Si device layer on the surface. This is important for blue color applications including DVD, medical diagnostics, fluorescence or the like.

Although the present invention has been shown and described with respect to several preferred embodiments thereof, various changes, omissions and additions to the form and detail thereof, may be made therein, without departing from the spirit and scope of the invention.

What is claimed is:

1. A photodiode comprising:
a Silicon-On-Insulator (SOI) substrate;
a plurality of interdigitated electrodes comprising of different doped regions defined on said SOI substrate; and
a silicon device region that is defined in the SOI substrate having a thickness between 0.5 and 5 microns.

2. The photodiode of claim 1, wherein said interdigitated electrodes comprise a p-n doped arrangement or p-i-n doped arrangement.

3. The photodiode of claim 1 further comprising an anti-reflection layer for preventing said trapped light to exit said silicon device layer.

4. The photodiode of claim 1 further comprising a grating layer for preventing said trapped light to exit said silicon device layer.

5. The photodiode of claim 1, wherein said grating layer is imprinted near the silicon device layer to direct and confine the diffracted orders into the silicon device layer in order to improve absorption.

6. The photodiode of claim 1, wherein said Si device layer is defined on a SOI substrate.

7. The photodiode of claim 1, wherein said interdigitated electrodes are defined on a SOI substrate.

8. A photodetector comprising:
a Silicon-On-Insulator (SOI) substrate; and
a plurality of photodiodes formed on said SOI substrate, each of said photodiodes comprising:
a plurality of interdigitated electrodes comprising of different doped regions; and
a silicon device region that is defined in the SOI substrate having a thickness between 0.5 and 5 microns.

9. The photodetector of claim 8, wherein said interdigitated electrodes comprise a p-n doped arrangement or p-i-n doped arrangement.

10. The photodetector of claim 8 further comprising an anti-reflection layer for increasing the absorption by reducing reflection at the boundary where light enters the said silicon device layer.

11. The photodetector of claim 8 further comprising a grating layer for preventing said trapped light to exit said silicon device layer.

12. The photodetector of claim 8, wherein said grating layer is imprinted near the silicon device layer to direct and confine the diffracted orders into the silicon device layer in order to improve absorption.

13. The photodetector of claim 8, wherein said Si device layer is defined on said SOI substrate.

14. The photodetector of claim 8, wherein said interdigitated electrodes are defined on said SOI substrate.

15. A method of forming a photodiode comprising:
providing a Silicon-On-Insulator (SOI) substrate
forming a plurality of interdigitated electrodes comprising of different doped regions on said SOI substrate; and
forming a silicon device region that is defined in the SOI substrate having a thickness between 0.5 and 5 microns.

16. The method of claim 15, wherein said interdigitated electrodes comprise a p-n doped arrangement or p-i-n doped arrangement.

17. The method of claim 15 further comprising forming an anti-reflection layer for preventing said trapped light to exit said silicon device layer.

18. The method of claim 15 further comprising forming a grating layer for preventing said trapped light to exit said silicon device layer.

19. The method of claim 15, wherein said grating layer is imprinted near the silicon device layer to direct and confine the diffracted orders into the silicon device layer in order to improve absorption.

20. The method of claim 15, wherein said Si device layer is defined on said SOI substrate.

21. The method of claim 15, wherein said interdigitated electrodes are defined on said SOI substrate.

22. The photodiode of claim 1, wherein said photodiode is integrated with signal conditioning electronics.

23. The photodetector of claim 8, wherein said photodetector is integrated with signal conditioning electronics

24. The method of claim 15, wherein said photodiode is integrated with with signal conditioning electronics.

25. The photodiode of claim 22, wherein said signal conditioning electronics are provided on the same SOI substrate.

26. The photodetector of claim 23, wherein said signal conditioning electronics are provided on the same SOI substrate.

27. The method of claim 24, wherein said signal conditioning electronics are provided on the same SOI substrate.

28. The photodiode of claim 22, wherein said signal conditioning electronics comprises of bipolar transistors.

29. The photodetector of claim 23, wherein said signal conditioning electronics comprises of bipolar transistors.

30. The method of claim 24, wherein said signal conditioning electronics comprises of bipolar transistors.

31. The photodiode of claim 22, wherein said signal conditioning electronics comprises of CMOS transistors.

32. The photodetector of claim 23, wherein said signal conditioning electronics comprises of CMOS transistors.

33. The method of claim 24, wherein said signal conditioning electronics comprises of CMOS transistors.
